(19) United States
(12) Patent Application Publication
(10) Pub. No.: US 2026/0080826 A1
(43) Pub. Date: Mar. 19, 2026

(54) DISPLAY DEVICE, MANUFACTURING METHOD THEREOF, AND ELCTRONIC DEVICE INCLUDING THE SAME

(71) Applicant: Samsung Display Co., Ltd., Yongin-si (KR)

(72) Inventors: Kyung-Tae KIM, Yongin-si (KR); Sangwoo SOHN, Yongin-si (KR); Hyunjun JEONG, Yongin-si (KR); Yeon Keon MOON, Yongin-si (KR); Jun Hyung LIM, Yongin-si (KR)

(73) Assignee: Samsung Display Co., Ltd., Yongin-si (KR)

(21) Appl. No.: 19/290,679

(22) Filed: Aug. 5, 2025

(30) Foreign Application Priority Data
Sep. 19, 2024 (KR) 10-2024-0126771

(51) Int. Cl. G09G 3/3233; H10D 86/01; H10D 86/40; H10D 86/60

(52) U.S. Cl. CPC G09G 3/3233; H10D 86/0221; H10D 86/423; H10D 86/441; H10D 86/60; G09G 2300/0426; G09G 2330/021; G09G 2354/00

(57) ABSTRACT

A display device includes multiple insulating layers, a light emitting element, and a pixel circuit electrically connected to the light emitting element. The pixel circuit includes a first transistor that controls a driving current of the light emitting element and a second transistor that outputs a data voltage. A first semiconductor pattern of the first transistor includes a crystalline indium gallium oxide (IGO) semiconductor, and a second semiconductor pattern of the second transistor includes an amorphous indium tin gallium zinc oxide (ITGZO) semiconductor.

### CROSS-REFERENCE TO RELATED APPLICATION(S)

This application claims priority to and the benefits of Korean Patent Application No. 10-2024-0126771 under 35 U.S.C. § 119, filed on Sep. 19, 2024, in the Korean Intellectual Property Office (KIPO), the entire contents of which are incorporated by reference herein in their entireties.

### BACKGROUND

### 1. Technical Field

Embodiments of the disclosure described herein relate to a display device including an oxide transistor, a method for manufacturing the display device, and an electronic device including the display device.

### 2. Description of the Related Art

A display device includes multiple pixels and a drive circuit (e.g., a scan drive circuit and a data drive circuit) that controls the pixels. Each of the pixels includes a display element and a pixel circuit that controls the display element. The pixel circuit may include multiple transistors in cooperation with one another.

The transistors may include a silicon semiconductor or a metal oxide semiconductor.

### SUMMARY

Embodiments of the disclosure provide a display device including an oxide transistor having a wide drive voltage range.

Embodiments of the disclosure provide a method for manufacturing a display device.

Embodiments of the disclosure provide an electronic device including a display device.

According to an embodiment, a display device may include a plurality of insulating layers, a light emitting element, and a pixel circuit electrically connected to the light emitting element. The pixel circuit may include a first transistor that controls a driving current of the light emitting element and includes a first semiconductor pattern including a crystalline indium gallium oxide (IGO) semiconductor and a second transistor that outputs a data voltage and includes a second semiconductor pattern including an amorphous indium tin gallium zinc oxide (ITGZO) semiconductor.

The first semiconductor pattern and the second semiconductor pattern may be in contact with an upper surface of a same one among the plurality of insulating layers.

The first transistor may further include a first gate electrode and a second gate electrode. The first semiconductor pattern may include a first channel area, a first input area, and a first output area. The first gate electrode may be disposed over the first channel area, and the second gate electrode may be disposed under the first channel area and may be electrically connected with the first output area.

The display device may further include a third transistor including a third semiconductor pattern including a silicon semiconductor.

The third semiconductor pattern may be in contact with an upper surface of one of the plurality of insulating layers, and the first semiconductor pattern and the second semiconductor pattern may be in contact with an upper surface of another one of the plurality of insulating layers.

The display device may further include a voltage line that receives a power supply voltage and is disposed under the first semiconductor pattern. The third transistor may further include a gate electrode disposed over the third semiconductor pattern. The gate electrode of the third transistor and the voltage line may be spaced apart from each other in a plan view and may be in contact with an upper surface of a same one among the plurality of insulating layers.

The display device may further include a conductive pattern disposed between the first semiconductor pattern and the voltage line. The conductive pattern may overlap the first semiconductor pattern and the voltage line in a plan view. An output area of the first semiconductor pattern and the conductive pattern may be electrically connected with each other.

The display device may further include a third transistor connected between a voltage line that receives a first voltage and a gate electrode of the first transistor, a fourth transistor connected between a voltage line that receives a second voltage and a first electrode of the light emitting element, and a fifth transistor connected between a voltage line that receives a first power supply voltage and the first transistor.

A second electrode of the light emitting element may receive a second power supply voltage different from the first power supply voltage.

The display device may further include a sixth transistor connected between the first transistor and the first electrode of the light emitting element.

A semiconductor pattern of each of the third transistor and the fourth transistor and the second semiconductor pattern may include a same semiconductor.

The semiconductor pattern of each of the third transistor and the fourth transistor and the second semiconductor pattern may be in contact with an upper surface of a same one among the plurality of insulating layers.

The fifth transistor may include a third semiconductor pattern including a silicon semiconductor.

According to an embodiment, an electronic device may include a display device and an input device that receives a command, an input, or data from outside. The display device may include a plurality of insulating layers, a light emitting element, and a pixel circuit electrically connected to the light emitting element. The pixel circuit may include a first transistor that controls a driving current of the light emitting element and includes a first semiconductor pattern including a crystalline indium gallium oxide (IGO) semiconductor and a second transistor that outputs a data voltage and includes a second semiconductor pattern including an amorphous indium tin gallium zinc oxide (ITGZO) semiconductor.

The input device may be an input sensor, a keyboard, or a mouse.

The first semiconductor pattern and the second semiconductor pattern may be in contact with an upper surface of a same one among the plurality of insulating layers.

The first transistor may further include a first gate electrode and a second gate electrode.

The first semiconductor pattern may include a first channel area, a first input area, and a first output area. The first gate electrode may be disposed over the first channel area, and the second gate electrode may be disposed under the first channel area and may be electrically connected with the first output area.

The electronic device may further include a third transistor including a third semiconductor pattern including a silicon semiconductor. The third semiconductor pattern may be in contact with an upper surface of one of the plurality of insulating layers, and the first semiconductor pattern and the second semiconductor pattern may be in contact with an upper surface of another one of the plurality of insulating layers.

According to an embodiment, a method for manufacturing a display device may include forming a first semiconductor pattern on an insulating layer, crystallizing the first semiconductor pattern, forming, on the insulating layer, a second semiconductor layer that covers the first semiconductor pattern, and forming a second semiconductor pattern to be spaced apart from the first semiconductor pattern in a plan view by patterning the second semiconductor layer. The first semiconductor pattern may include an indium gallium oxide (IGO) semiconductor, and the second semiconductor pattern may include an indium tin gallium zinc oxide (ITGZO) semiconductor.

The method may further include forming a first gate electrode over the first semiconductor pattern and forming a second gate electrode over the second semiconductor pattern.

The method may further include forming, between the first semiconductor pattern and the first gate electrode, an insulating pattern that exposes portions of the first semiconductor pattern.

### BRIEF DESCRIPTION OF THE DRAWINGS

The above and other objects and features of the disclosure will become apparent by describing in detail embodiments thereof with reference to the accompanying drawings.

FIGS. 1A and 1B are perspective views of an electronic device according to an embodiment of the disclosure.

FIG. 1C is a schematic block diagram of the electronic device according to an embodiment of the disclosure.

FIG. 2 is a schematic block diagram of a display device according to an embodiment of the disclosure.

FIG. 3A is a schematic diagram of an equivalent circuit of a pixel according to an embodiment of the disclosure.

FIG. 3B is a schematic waveform diagram of drive signals for driving the pixel illustrated in FIG. 3A.

FIG. 4A is a schematic diagram of an equivalent circuit of a pixel according to an embodiment of the disclosure.

FIG. 4B is a schematic waveform diagram of drive signals for driving the pixel illustrated in FIG. 4A.

FIG. 5 is a schematic cross-sectional view of a display panel according to an embodiment of the disclosure.

FIG. 6A is a graph depicting voltage-current characteristics of an oxide transistor according to a comparative example.

FIG. 6B is a graph depicting voltage-current characteristics of an oxide transistor according to an embodiment of the disclosure.

FIG. 6C is a graph depicting voltage-current characteristics of an oxide transistor according to an embodiment of the disclosure.

FIGS. 7A to 7H are schematic cross-sectional views illustrating a manufacturing process of the display panel according to an embodiment of the disclosure.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Identical reference numerals refer to identical components. Additionally, in the drawings, the thicknesses, proportions, and dimensions of components are exaggerated for effective description.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component. The terms of a singular form may include plural forms unless otherwise specified.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Hereinafter, embodiments of the disclosure will be described with reference to the accompanying drawings.

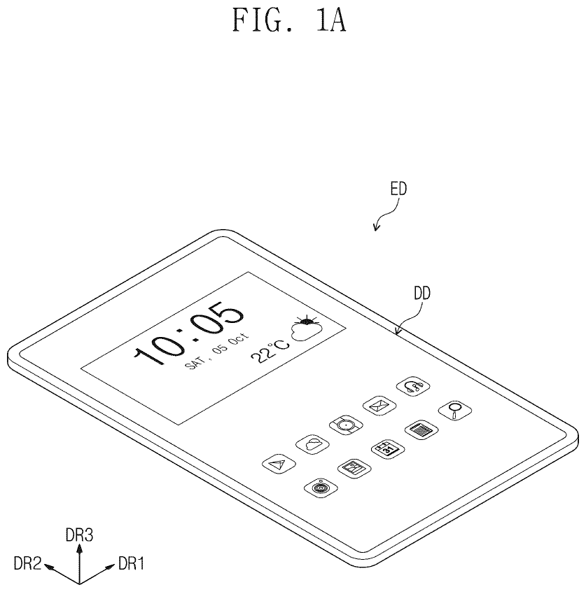

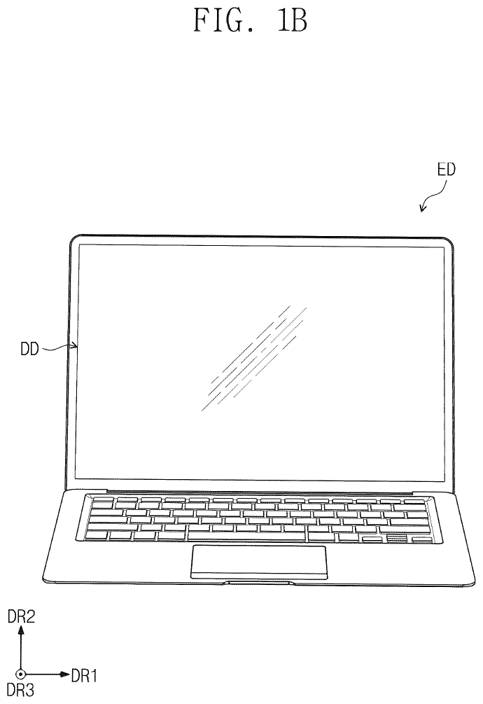

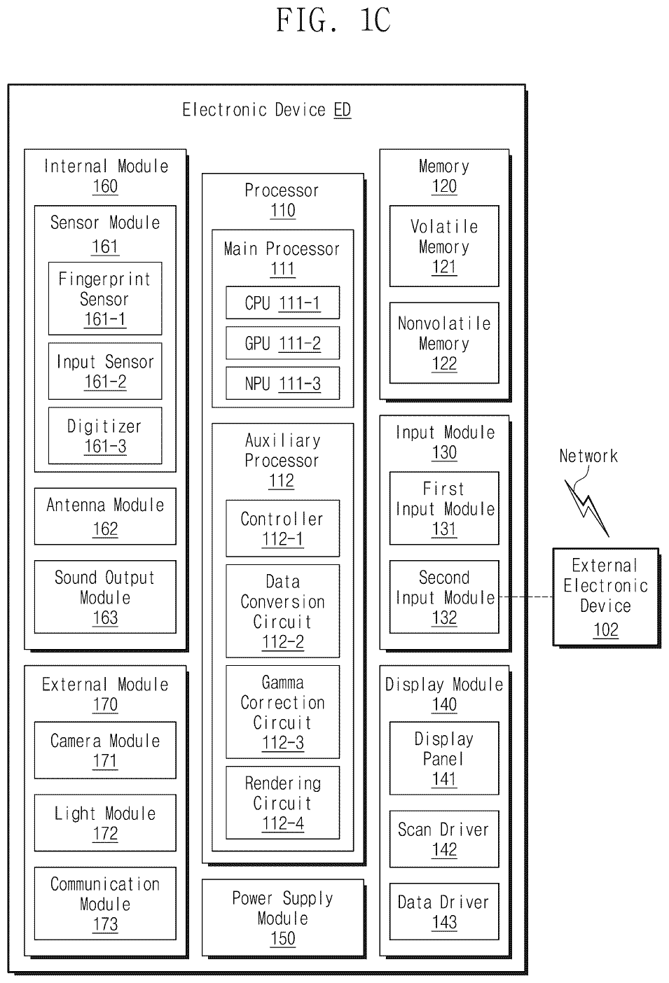

FIGS. 1A and 1B are perspective views of an electronic device ED according to an embodiment of the disclosure. FIG. 1C is a schematic block diagram of the electronic device ED according to an embodiment of the disclosure.

The electronic device ED according to an embodiment of the disclosure may include a display device DD. The electronic device ED according to an embodiment of the disclosure may be a tablet computer illustrated in FIG. 1A or a notebook computer illustrated in FIG. 1B.

The electronic device ED according to an embodiment of the disclosure may be an image display electronic device such as a smartphone, a television (TV), and a desk monitor, a wearable electronic device including a display module such as a smart glasses, a head mounted display, and a smart watch, and a vehicle electronic device including a display module such as an instrument panel, a center fascia, a center information display (CID) disposed on a dashboard, and a room mirror display of a vehicle.

As illustrated in FIG. 1C, the electronic device ED may output various pieces of information through a display module 140 in an operating system. The display device DD described with reference to FIGS. 1A and 1B may include a display module 140. In case that a processor 110 executes an application stored in a memory 120, the display module 140 may provide application information to a user through a display panel 141.

The processor 110 may obtain an external input through an input module 130 or a sensor module 161 and execute an application corresponding to the external input. For example, in case that the user selects a camera icon displayed on the display panel 141, the processor 110 may obtain the user input through an input sensor 161-2 and activate a camera module 171. The processor 110 may transfer image data corresponding to a photographed image obtained through the camera module 171 to the display module 140. The display module 140 may display an image corresponding to the photographed image through the display panel 141.

For example, in case that authentication for personal information is performed in the display module 140, a fingerprint sensor 161-1 may obtain input fingerprint information as input data. The processor 110 may compare the input data obtained through the fingerprint sensor 161-1 with authentication data stored in the memory 120 and execute an application depending on a comparison result. The display module 140 may display, through the display panel 141, information executed depending on logic of the application.

For example, in case that the user selects a music streaming icon displayed on the display module 140, the processor 110 may obtain the user input through the input sensor 161-2 and activate a music streaming application stored in the memory 120. In case that a music play command is input to the music streaming application, the processor 110 may activate a sound output module 163 and provide sound information corresponding to the music play command to the user.

The operation of the electronic device ED has been briefly described above. Hereinafter, a configuration of the electronic device ED will be described in detail. Some of the components of the electronic device ED described below may be integrally implemented in one component, or a component may be divided into two or more components.

Referring to FIG. 1C, the electronic device ED may communicate with an external electronic device 102 over a network (e.g., a short-range wireless communication network or a long-range wireless communication network). According to an embodiment, the electronic device ED may include the processor 110, the memory 120, the input module 130, the display module 140, a power supply module 150, an internal module 160, and an external module 170. According to an embodiment, the electronic device ED may not include at least one of the above-described components or may further include one or more other components. According to an embodiment, some of the above-described components (e.g., the sensor module 161, an antenna module 162, or the sound output module 163) may be integrated into another component (e.g., the display module 140).

The processor 110 may execute software to control at least one other component (e.g., a hardware or software component) of the electronic device ED connected to the processor 110 and may perform various data processing or operations. According to an embodiment, as at least a part of the data processing or operations, the processor 110 may store a command or data received from another component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include at least one of a central processing unit (CPU) 111-1 and an application processor (AP). The main processor 111 may further include at least one of a graphic processing unit (GPU) 111-2, a communication processor (CP), and an image signal processor (ISP). The main processor 111 may further include a neural processing unit (NPU) 111-3. The neural processing unit 111-3 may be a processor specialized for processing of an artificial intelligence model, and the artificial intelligence model may be created through machine learning. The artificial intelligence model may include multiple artificial neural network layers. The artificial neural network may include a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof, but the disclosure is not limited thereto. Additionally or alternatively, the artificial intelligence model may include a software structure in addition to a hardware structure. At least two of the above-described processing units and processors may be integrally implemented in one component (e.g., a single chip), or each of the above-described processing units and processors may be implemented in an independent component (e.g., multiple chips).

The auxiliary processor 112 may include a controller 112-1. The controller 112-1 may include an interface conversion circuit and a timing control circuit. The controller 112-1 may receive an image signal from the main processor 111 and output image data obtained by converting the data format of the image signal according to the specification of an interface with the display module 140. The controller 112-1 may output various types of control signals required to drive the display module 140.

The auxiliary processor 112 may further include a data conversion circuit 112-2, a gamma correction circuit 112-3, and a rendering circuit 112-4. The data conversion circuit 112-2 may receive image data from the controller 112-1. The data conversion circuit 112-2 may compensate the image data such that an image is displayed with a desired luminance depending on a characteristic of the electronic device ED or user settings or may convert the image data to reduce power consumption or to compensate for afterimages. The gamma correction circuit 112-3 may convert the image data or the gamma reference voltage such that an image displayed on the electronic device ED has a desired gamma characteristic. The rendering circuit 112-4 may receive the image data from the controller 112-1 and may make the image data subject to rendering in consideration of a pixel arrangement of the display panel 141 applied to the electronic device ED. At least one of the data conversion circuit 112-2, the gamma correction circuit 112-3, and the rendering circuit 112-4 may be integrated into another component (e.g., the main processor 111 or the controller 112-1). At least one of the data conversion circuit 112-2, the gamma correction circuit 112-3, and the rendering circuit 112-4 may be integrated in a data driver 143 described below.

The memory 120 may store various data used by at least one component (e.g., the processor 110 or the sensor module 161) of the electronic device ED and input data or output data for commands related thereto. The memory 120 may include at least one of the volatile memory 121 and the nonvolatile memory 122.

The input module 130 may receive a command or data to be used by a component (e.g., the processor 110, the sensor module 161, or the sound output module 163) of the electronic device ED from the outside of the electronic device ED (e.g., the user or the external electronic device 102).

The input module 130 may include a first input module 131 to which a command or data is input from the user and a second input module 132 to which a command or data is input from the external electronic device 102. The first input module 131 may include a microphone, a mouse, a keyboard, a key (e.g., a button), or a pen (e.g., a passive pen or an active pen). The second input module 132 may support a specified protocol for wired or wireless connection to the external electronic device 102. According to an embodiment, the second input module 132 may include a high definition multimedia interface (HDMI), a universal serial bus (USB) interface, a secure digital (SD) card interface, or an audio interface. The second input module 132 may include a connector capable of being physically connected with the external electronic device 102, for example, an HDMI connector, a USB connector, an SD card connector, or an audio connector (e.g., a headphone connector).

The display module 140 may visually provide information to the user. The display module 140 may include the display panel 141, a scan driver 142, and the data driver 143. The display module 140 may further include a window, a chassis, or a bracket for protecting the display panel 141.

The display panel 141 may include a liquid crystal display panel, an organic light emitting display panel, or an inorganic light emitting display panel, and the type of the display panel 141 is not particularly limited. The display panel 141 may be of a rigid type or may be of a flexible type capable of being rolled or folded. The display module 140 may further include a supporter that supports the display panel 141, a bracket, or a heat radiating member.

The scan driver 142 may be a driver chip and may be mounted on the display panel 141. In another embodiment, the scan driver 142 may be integrated into the display panel 141. For example, the scan driver 142 may include an amorphous silicon TFT gate driver circuit (ASG), a low temperature polycrystalline silicon (LTPS) TFT gate driver circuit, or an oxide semiconductor TFT gate driver circuit (OSG) embedded in the display panel 141. The scan driver 142 may receive a control signal from the controller 112-1 and output scan signals to the display panel 141 in response to the control signal.

The display panel 141 may further include an emission driver. The emission driver may output an emission control signal to the display panel 141 in response to a control signal received from the controller 112-1. The emission driver may be formed separately from the scan driver 142 or may be integrated into the scan driver 142.

The data driver 143 may receive a control signal from the controller 112-1, convert image data into analog voltages (e.g., data voltages) in response to the control signal, and output the data voltages to the display panel 141.

The data driver 143 may be integrated into another component (e.g., the controller 112-1). The functions of the interface conversion circuit and the timing control circuit of the controller 112-1 described above may be integrated into the data driver 143.

The display module 140 may further include the emission driver and a voltage generation circuit. The voltage generation circuit may output various types of voltages required to drive the display panel 141.

The power supply module 150 may supply power to the components of the electronic device ED. The power supply module 150 may include a battery that charges a power supply voltage. The battery may include a primary cell that is not rechargeable, a secondary cell that is rechargeable, or a fuel cell. The power supply module 150 may include a power management integrated circuit (PMIC). The PMIC may supply power optimized for the modules described above and modules described below. The power supply module 150 may include a wireless power transmission/reception member electrically connected with the battery. The wireless power transmission/reception member may include multiple antenna radiators in the form of a coil.

The electronic device ED may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may sense an input by the user's body or an input by a pen of the first input module 131 and may generate an electrical signal or a data value corresponding to the input. The sensor module 161 may include at least one of the fingerprint sensor 161-1, the input sensor 161-2, and a digitizer 161-3. The input module 130 and the sensor module 161 that receive a command, an input, or data from the outside may be collectively referred to as an input device.

The fingerprint sensor 161-1 may generate a data value corresponding to the user's fingerprint. The fingerprint sensor 161-1 may include at least one of an optical fingerprint sensor and a capacitive fingerprint sensor.

The input sensor 161-2 may generate a data value corresponding to coordinate information of the input by the user's body or the input by the pen. The input sensor 161-2 may generate a capacitance change due to the input as a data value. The input sensor 161-2 may sense the input by the passive pen or may exchange data with the active pen.

The input sensor 161-2 may measure a biometric signal such as blood pressure, moisture, or body fat. For example, in case that the user touches his/her body part to a sensor layer or a sensing panel and does not move for a given time period, the input sensor 161-2 may detect the biometric signal based on a change in an electric field caused by the body part and may output the information desired by the user to the display module 140.

The digitizer 161-3 may generate a data value corresponding to the coordinate information of the input by the pen. The digitizer 161-3 may generate the amount of electromagnetic change by the input as a data value. The digitizer 161-3 may sense the input by the passive pen or may exchange data with the active pen.

At least one of the fingerprint sensor 161-1, the input sensor 161-2, and the digitizer 161-3 may be implemented in a sensor layer formed on the display panel 141 through a continuous process. The fingerprint sensor 161-1, the input sensor 161-2, and the digitizer 161-3 may be disposed above or on the display panel 141, and at least one of the fingerprint sensor 161-1, the input sensor 161-2, and the digitizer 161-3, for example, the digitizer 161-3 may be disposed below or under the display panel 141.

At least two of the fingerprint sensor 161-1, the input sensor 161-2, and the digitizer 161-3 may be integrated into one sensing panel through a same process. In case that at least two of the fingerprint sensor 161-1, the input sensor 161-2, and the digitizer 161-3 are integrated into one sensing panel, the sensing panel may be disposed between the display panel 141 and the window disposed above or on the display panel 141. According to an embodiment, the sensing panel may be disposed on the window, but the location of the sensing panel is not specifically limited.

At least one of the fingerprint sensor 161-1, the input sensor 161-2, and the digitizer 161-3 may be embedded in the display panel 141. For example, at least one of the fingerprint sensor 161-1, the input sensor 161-2, and the digitizer 161-3 may be simultaneously formed through a process of forming elements (e.g., a light emitting element and transistors) included in the display panel 141.

The sensor module 161 may generate an electrical signal or a data value corresponding to a state inside the electronic device ED or a state outside of the electronic device ED. The sensor module 161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit or receive a signal or power to or from an external source. According to an embodiment, through an antenna suitable for a communication method, the communication module 173 may transmit a signal to an external electronic device or may receive a signal from the external electronic device. An antenna pattern of the antenna module 162 may be integrated in a component (e.g., the display panel 141) of the display module 140 or the input sensor 161-2.

The sound output module 163, which is a device for outputting a sound signal to the outside of the electronic device ED, may include, for example, a speaker used for general purposes such as playing multimedia or playing record and a receiver used exclusively for receiving calls. According to an embodiment, the receiver and the speaker may be integrally or separately implemented. A sound output pattern of the sound output module 163 may be integrated in the display module 140.

The camera module 171 may photograph a still image and a moving image. According to an embodiment, the camera module 171 may include one or more lenses, an image sensor, or an image signal processor. The camera module 171 may further include an infrared camera capable of measuring the presence or absence of the user, the location of the user, and the user's gaze.

The light module 172 may provide light. The light module 172 may include a light emitting diode or a xenon lamp. The light module 172 may operate in conjunction with the camera module 171 or may operate independently of the camera module 171.

The communication module 173 may establish a wired or wireless communication channel between the electronic device ED and the external electronic device 102 and may support communication through the established communication channel. The communication module 173 may include either or both of a wireless communication module, such as a cellular communication module, a short-range wireless communication module, or a global navigation satellite system (GNSS) communication module, and a wired communication module, such as a local area network (LAN) communication module or a power line communication module. The communication module 173 may communicate with the external electronic device 102 over a short-range communication network such as Bluetooth, Wi-Fi direct, or infrared data association (IrDA) or a long-range communication network such as a cellular network, the Internet, or a computer network (e.g., a LAN or WAN). Various types of communication modules 173 described above may be implemented in one chip or may be implemented in separate chips, respectively.

The input module 130, the sensor module 161, and the camera module 171 may be used to control the operation of the display module 140 in conjunction with the processor 110.

The processor 110 may output commands or data to the display module 140, the sound output module 163, the camera module 171, or the light module 172 based on input data received from the input module 130. For example, the processor 110 may generate the image data corresponding to the input data applied through the mouse or the active pen and may output the image data to the display module 140. For example, the processor 110 may generate command data corresponding to the input data and may output the command data to the camera module 171 or the light module 172. In case that input data is not received from the input module 130 for a time period, the processor 110 may switch an operating mode of the electronic device ED to a low-power mode or a sleep mode such that the power consumption of the electronic device ED is reduced.

The processor 110 may output commands or data to the display module 140, the sound output module 163, the camera module 171, or the light module 172 based on the sensing data received from the sensor module 161. For example, the processor 110 may compare authentication data applied by the fingerprint sensor 161-1 with authentication data stored in the memory 120 and may execute an application depending on a comparison result. The processor 110 may execute a command based on the sensing data sensed by the input sensor 161-2 or the digitizer 161-3 or may output image data corresponding to the sensing data to the display module 140. In case that the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and the user's gaze from the camera module 171. The processor 110 may further perform the luminance correction on the image data based on the measurement data. For example, the processor 110 that determines the presence or absence of the user through the input from the camera module 171 may output, to the display module 140, image data whose luminance is corrected through the data conversion circuit 112-2 or the gamma correction circuit 112-3.

Some of the above-described components may be connected with each other through a communication method between peripheral devices, for example, a bus, a general purpose input/output (GPIO), a serial peripheral interface (SPI), a mobile industry processor interface (MIPI), or a ultra path interconnect (UPI) link and may exchange signals (e.g., commands or data) with each other. The processor 110 may communicate with the display module 140 through an interface. For example, one of the communication methods described above may be used, and the disclosure is not limited thereto.

The electronic device ED according to various embodiments of the disclosure may be implemented as various types of devices. The electronic device ED may include, for example, at least one of a portable communication device (e.g., a smart phone), a computer device, a portable multimedia device, a portable medical device, a camera, a wearable device, and home appliances. The electronic device ED is not limited to the above-described devices.

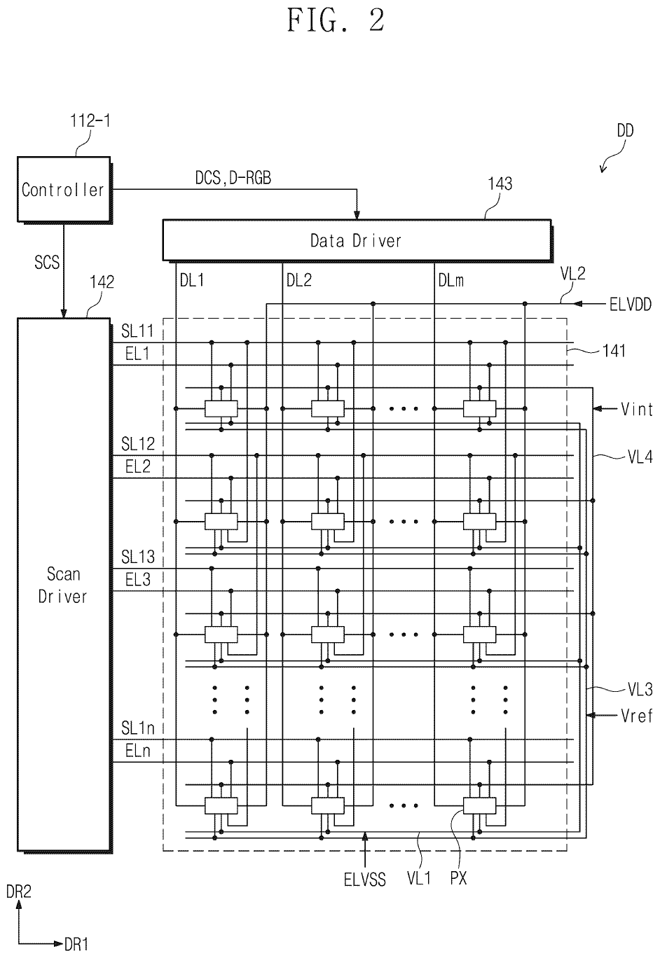

FIG. 2 is a schematic block diagram of the display device DD according to an embodiment of the disclosure. The display device DD may include the controller 112-1, the display panel 141, the scan driver 142, and the data driver 143. In an embodiment, the display panel 141 may be an emissive display panel. The emissive display panel may include an organic light emitting display panel or an inorganic light emitting display panel.

The controller 112-1 may generate image data D-RGB by converting the data format of input image signals according to the specification of an interface with the scan driver 142. The controller 112-1 may output the image data D-RGB and various types of control signals DCS and SCS.

The scan driver 142 may receive the scan control signal SCS from the controller 112-1. The scan control signal SCS may include a vertical start signal to start an operation of the scan driver 142 and a clock signal to determine the time to output signals. The scan driver 142 may generate multiple scan signals and sequentially output the scan signals to corresponding scan lines SL11 to SL1n. The scan driver 142 may generate multiple emission control signals in response to the scan control signal SCS and output the emission control signals to corresponding emission lines EL1 to ELn.

In FIG. 2, the scan signals and the emission control signals are illustrated as being output from one scan driver 142. However, the disclosure is not limited thereto. In another embodiment of the disclosure, the display device DD may include multiple scan driver circuits. In another embodiment of the disclosure, a drive circuit for generating and outputting multiple scan signals and a drive circuit for generating and outputting multiple emission control signals may be separately formed.

The data driver 143 may receive the data control signal DCS and the image data D-RGB from the controller 112-1. The data driver 143 may convert the image data D-RGB into data signals and output the data signals to multiple data lines DL1 to DLm described below. The data signals may be analog voltages corresponding to gray level values of the image data D-RGB.

The display panel 141 may include multiple groups of scan lines. In FIG. 2, a first group of scan signal lines SL11 to SL1n are illustrated according to an embodiment. The display panel 141 may further include the emission signal lines EL1 to ELn, the data lines DL1 to DLm, a first voltage line VL1, a second voltage line VL2, a third voltage line VL3, a fourth voltage line VL4, and multiple pixels PX.

The first group of scan signal lines SL11 to SL1n may extend in a first direction DR1 and may be arranged in a second direction DR2. The data lines DL1 to DLm may intersect the first group of scan signal lines SL11 to SL1n.

The first voltage line VL1 may receive a first power supply voltage ELVSS. The second voltage line VL2 may receive a second power supply voltage ELVDD. The second power supply voltage ELVDD may have a higher level than the first power supply voltage ELVSS. The third voltage line VL3 may receive a reference voltage Vref (hereinafter, referred to as the first voltage). The fourth voltage line VL4 may receive an initialization voltage Vint (hereinafter, referred to as the second voltage). The first voltage Vref may have a lower level than the second power supply voltage ELVDD. The second voltage Vint may have a lower level than the second power supply voltage ELVDD. In an embodiment, the second voltage Vint may have a lower level than the first voltage Vref and the first power supply voltage ELVSS.

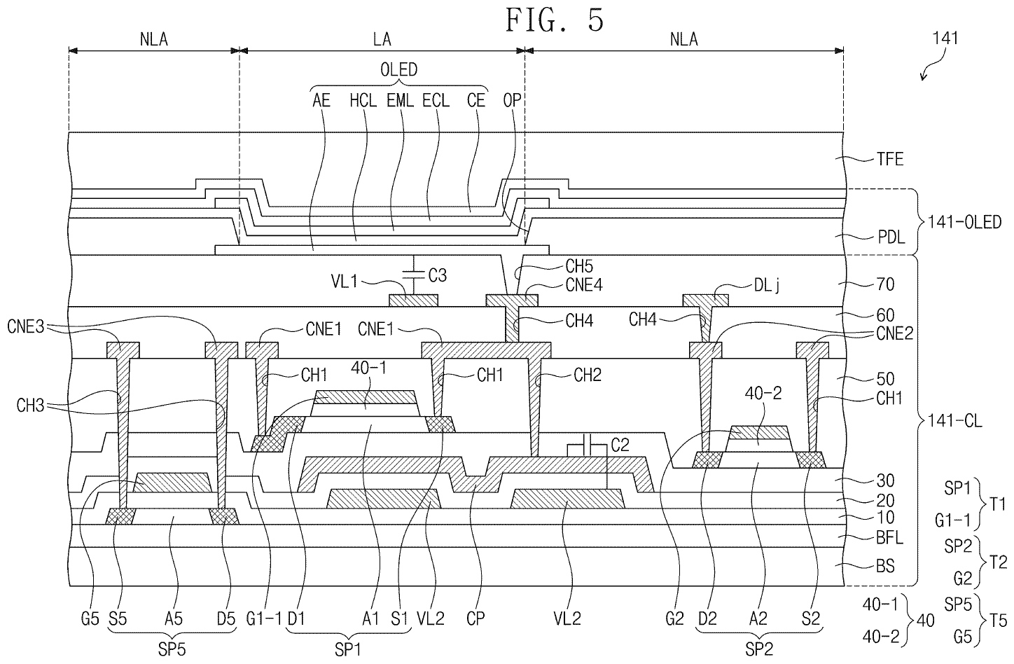

At least one of the first voltage line VL1, the second voltage line VL2, the third voltage line VL3, and the fourth voltage line VL4 may include at least one of a line extending in the first direction DR1 and a line extending in the second direction DR2. The line of the voltage line that extends in the first direction DR1 and the line of the voltage line that extends in the second direction DR2 may be electrically connected with each other even though the lines are disposed on different layers among multiple insulating layers 10 to 40 illustrated in FIG. 5.

Although the display device DD according to an embodiment has been described with reference to FIG. 2, the disclosure is not limited thereto. Signal lines may be added or omitted depending on the configuration of a pixel circuit, and a connection relationship between a pixel PX and the signal lines may also be changed.

The pixels PX may include multiple groups that generate light of different colors. For example, the pixels PX may include red pixels that generate red light, green pixels that generate green light, and blue pixels that generate blue light. Light emitting elements of the red pixels, light emitting elements of the green pixels, and light emitting elements of the blue pixels may include emissive layers formed of different materials.

The pixel circuit may include multiple transistors and at least one capacitor. At least one of the scan driver 142 and the data driver 143 may include multiple transistors formed through a same process as the pixel circuit.

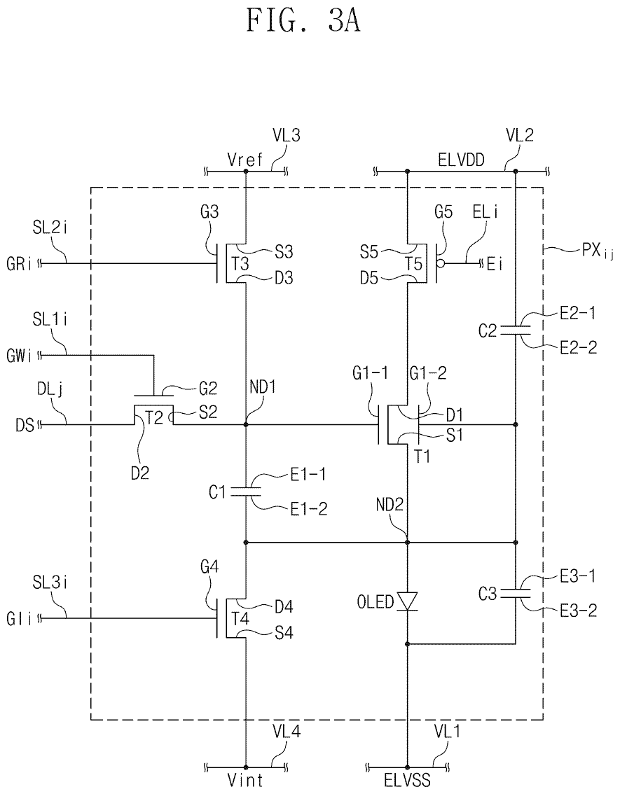

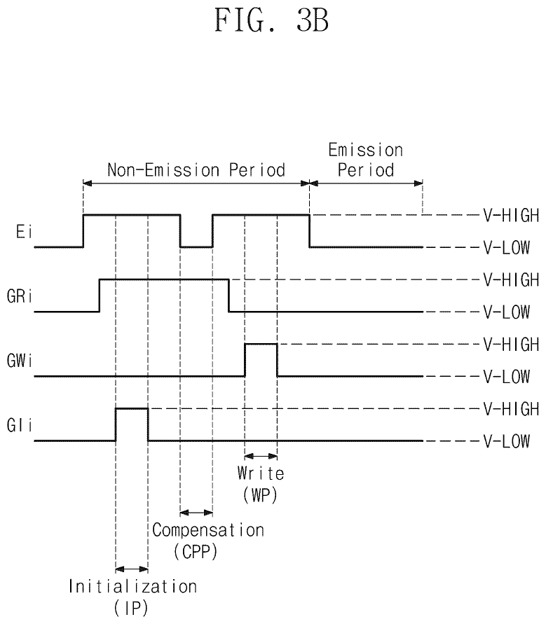

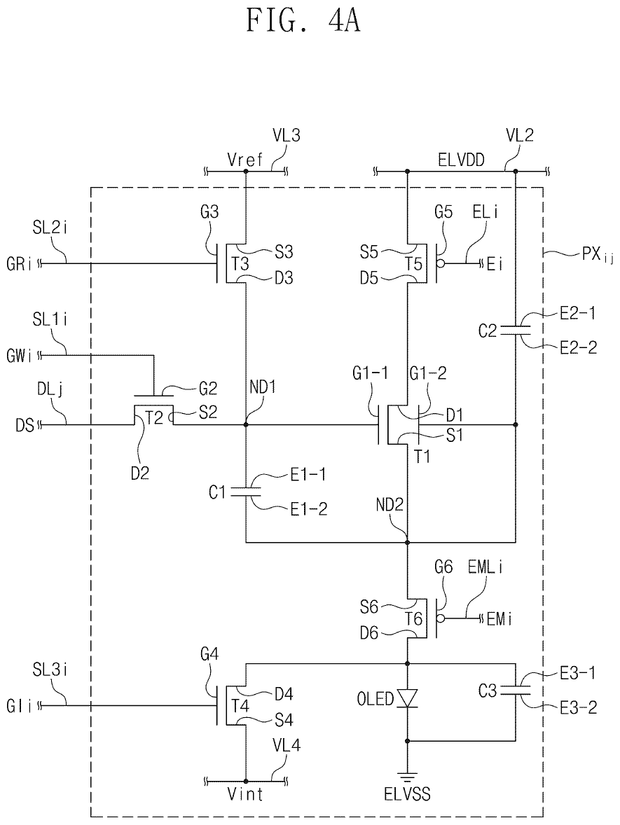

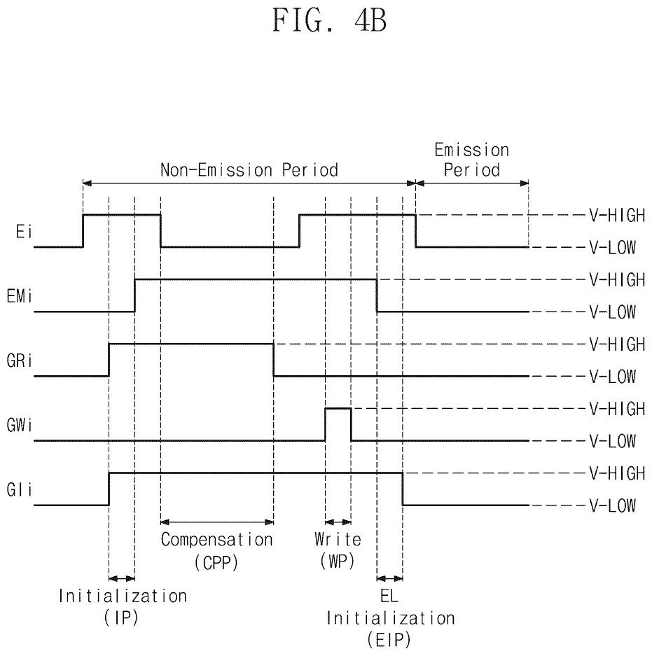

FIG. 3A is a schematic diagram of an equivalent circuit of a pixel PXij according to an embodiment of the disclosure. FIG. 3B is a schematic waveform diagram of drive signals for driving the pixel PXij illustrated in FIG. 3A. FIG. 4A is a schematic diagram of an equivalent circuit of a pixel PXij according to an embodiment of the disclosure. FIG. 4B is a schematic waveform diagram of drive signals for driving the pixel PXij illustrated in FIG. 4A.

In FIG. 3A, the pixel PXij connected to the i-th scan line SL11 among the first group of scan lines SL11 to SL1n (refer to FIG. 2) and the j-th data line DLj among the data lines DL1 to DLm (refer to FIG. 2) is representatively illustrated. The pixel PXij may be connected to the i-th scan line SL2i among the second group of scan lines and the i-th scan line SL3i among the third group of scan lines.

In an embodiment, a pixel circuit may include first to fifth transistors T1 to T5, first to third capacitors C1 to C3, and a light emitting element OLED. In FIG. 3A, the first to fourth transistors T1 to T4 is described as N-type transistors, and the fifth transistor T5 is described as a P-type transistor according to an embodiment. In another embodiment of the disclosure, the third capacitor C3 may be omitted.

In an embodiment, the first transistor T1 may include two gates, and the second to fifth transistors T2 to T5 may include one gate. However, the disclosure is not limited thereto, and in another embodiment, at least one of the second to fifth transistors T2 to T5 may include two gates.

In an embodiment, the first transistor T1 may be a drive transistor, and the second transistor T2 may be a switching transistor. A node to which a gate G1-1 (hereinafter, referred to as the first upper gate) of the first transistor T1 is connected may be defined as a first node ND1, and a node to which a source S1 of the first transistor T1 is connected may be defined as a second node ND2. The first capacitor C1 may be electrically connected to the first node ND1, and the light emitting element OLED may be electrically connected to the second node ND2.

The light emitting element OLED may include a first electrode electrically connected to the second node ND2, a second electrode electrically connected with the first voltage line VL1 that receives the first power supply voltage ELVSS, and an emissive layer disposed between the first electrode and the second electrode. Detailed description of the light emitting element OLED will be given below.

The first transistor T1 may be electrically connected between the second voltage line VL2, which receives the second power supply voltage ELVDD, and the second node ND2. The first transistor T1 may include the source S1 (hereinafter, referred to as the first source) connected to the second node ND2, a drain D1 (hereinafter, referred to as the first drain), a channel area (or, a semiconductor area), and the first upper gate G1-1. The first transistor T1 may further include a gate G1-2 (hereinafter, referred to as the first lower gate) connected to the second node ND2. The first transistor T1 may control a driving current or on-current (Ion) of the light emitting element OLED based on the charging capacitance of the first capacitor C1.

The second transistor T2 may be electrically connected between the first data line DLj and the first node ND1. The second transistor T2 may include a source S2 (hereinafter, referred to as the second source) connected to the first node ND1, a drain D2 (hereinafter, referred to as the second drain) connected to the first data line DLj, a channel area, and a gate G2 connected to the i-th scan line SL11 of the first group. The second transistor T2 may output a data voltage. The first capacitor C1 may receive the data voltage.

The third transistor T3 may be electrically connected between the first node ND1 and the third voltage line VL3 that receives the first voltage Vref. The third transistor T3 may include a drain D3 (hereinafter, referred to as the third drain) connected to the first node ND1, a source S3 (hereinafter, referred to as the third source) connected to the third voltage line VL3, a channel area, and a gate G3 connected to the i-th scan line SL2i of the second group.

The fourth transistor T4 may be electrically connected between the fourth voltage line VL4, which receives the second voltage Vint, and the second node ND2. The fourth transistor T4 may include a drain D4 (hereinafter, referred to as the fourth drain) connected to the second node ND2, a source S4 (hereinafter, referred to as the fourth source) connected to the fourth voltage line VL4, a channel area, and a gate G4 connected to the i-th scan line SL3i of the third group.

The fifth transistor T5 may be electrically connected between the second voltage line VL2 and the first drain D1 or the first source S1. In an embodiment, the fifth transistor T5 may include a source S5 (hereinafter, referred to as the fifth source) connected to the second voltage line VL2, a drain D5 (hereinafter, referred to as the fifth drain) connected to the first drain D1, a channel area, and a fifth gate G5 connected to the i-th emission signal line ELi.

The first capacitor C1 may be electrically connected between the first node ND1 and the second node ND2. The first capacitor C1 may include a first electrode E1-1 connected to the first node ND1 and a second electrode E1-2 connected to the second node ND2.

The second capacitor C2 may be electrically connected between the second voltage line VL2 and the second node ND2. The second capacitor C2 may include a first electrode E2-1 connected to the second voltage line VL2 and a second electrode E2-2 connected to the second node ND2.

The third capacitor C3 may be electrically connected between the first electrode and the second electrode of the light emitting element OLED. The third capacitor C3 may include a first electrode E3-1 connected to the first electrode of the light emitting element OLED and a second electrode E3-2 connected to the second electrode of the light emitting element OLED.

An operation of the pixel PXij will be described in more detail with reference to FIGS. 3A and 3B. The display device DD (refer to FIG. 2) may display an image for each of frame periods. The first group of scan lines, the second group of scan lines, the third group of scan lines, and the emission signal lines may be sequentially scanned during the frame period. FIG. 3B schematically illustrates a portion of the frame period.

Referring to FIG. 3B, each of signals Ei, GRi, GWi, and Gli may have a high level V-HIGH during some periods and may have a low level V-LOW during other periods. The first to fourth transistors T1 to T4 of an N-type, which have been described above, may be turned on in case that a corresponding control signal has the high level V-HIGH. The fifth transistor T5 of a P-type, which has been described above, may be turned on in case that a corresponding control signal has the low level V-LOW.

During an initialization period IP, the third transistor T3 and the fourth transistor T4 may be turned on. The first node ND1 may be initialized to the first voltage Vref. The second node ND2 may be initialized to the second voltage Vint. The first capacitor C1 may be initialized to a voltage difference between the first voltage Vref and the second voltage Vint. The second capacitor C2 may be initialized to a voltage difference between the second power supply voltage ELVDD and the second voltage Vint. The third capacitor C3 may be initialized to a voltage difference between the first power supply voltage ELVSS and the second voltage Vint.

During a compensation period CPP, the third transistor T3 and the fifth transistor T5 may be turned on. The first voltage Vref is supplied to the first node ND1, and the second power supply voltage ELVDD is supplied to the first drain area D1 of the first transistor T1, so that the first transistor T1 can be turned on. When the voltage of the first source area S1 of the first transistor T1 reaches a voltage difference between the first voltage Vref and the threshold voltage Vth of the first transistor T1, the first transistor T1 can be turned off. A voltage corresponding to the threshold voltage Vth of the first transistor T1 is stored in the first capacitor C1, so that the threshold voltage Vth of the first transistor T1 can be compensated to the first capacitor C1.

During a write period WP, the second transistor T2 may be turned on. The second transistor T2 may output a voltage (or, a data voltage) corresponding to a data signal DS. As a result, the first capacitor C1 may be charged with a voltage level corresponding to the data signal DS. The first capacitor C1 may be charged with the data signal DS obtained by compensating for the threshold voltage of the first transistor T1. The threshold voltages of the drive transistors of the pixels PX (refer to FIG. 2) may be different from one another, but the pixel PXij illustrated in FIG. 3A may supply a current proportional to the data signal DS to the light emitting element OLED irrespective of the threshold voltage difference between the drive transistors.

Thereafter, during an emission period, the fifth transistor T5 may be turned on. The first transistor T1 may provide a current corresponding to the charging capacity stored in the first capacitor C1 to the light emitting element OLED. The light emitting element OLED may emit light with a luminance corresponding to the data signal DS.

The pixel PXij illustrated in FIG. 4A will be described focusing on the difference from the pixel PXij illustrated in FIG. 3A. The pixel circuit of FIG. 4A may further include a sixth transistor T6. In an embodiment, the sixth transistor T6 may be a P-type transistor, but the disclosure is not particularly limited thereto. The pixel circuit of FIG. 4A may be different from the pixel circuit of FIG. 3A in terms of the connection relationship between the fourth transistor T4 and other transistors.

The sixth transistor T6 may be electrically connected between the second node ND2 and the first electrode of the light emitting element OLED. In an embodiment, the sixth transistor T6 may include a source S6 (hereinafter, referred to as the sixth source) connected to the second node ND2, a drain D6 (hereinafter, referred to as the sixth drain) connected to the first electrode of the light emitting element OLED, a channel area, and a sixth gate G6 connected to the i-th emission signal line EMLi. In case that the i-th emission signal line ELi connected to the fifth gate G5 is defined as an emission signal line of a first group, the i-th emission signal line EMLi connected to the sixth gate G6 may be defined as an emission signal line of a second group. The drain D4 of the fourth transistor T4 may be connected to the first electrode of the light emitting element OLED and the sixth drain D6.

Referring to FIG. 4B, during the initialization period IP, the third transistor T3, the fourth transistor T4, and the sixth transistor T6 may be turned on. The first capacitor C1 may be initialized to a voltage difference between the first voltage Vref and the second voltage Vint.

The period in which both the third transistor T3 and the fifth transistor T5 are turned on may correspond to the compensation period CPP. The fourth transistor T4 may initialize the first electrode of the light emitting element OLED until the fourth transistor T4 is turned off after being turned on. An EL initialization period EIP may be located after the write period WP. During the EL initialization period EIP, the fourth transistor T4 and the sixth transistor T6 may be turned on. The first electrode of the light emitting element OLED and the second node ND2 may be initialized to the second voltage Vint.

FIG. 5 is a schematic cross-sectional view of the display panel 141 according to an embodiment of the disclosure. The illustration of FIG. 5 focuses on the first transistor T1, the second transistor T2, and the fifth transistor T5 of FIG. 3A.

Referring to FIG. 5, the display panel 141 may include a base layer BS and a circuit element layer 141-CL, a display element layer 141-OLED, and a thin film encapsulation layer TFE that are disposed on the base layer BS. Although not illustrated, the display panel 141 may further include functional layers, such as an anti-reflective layer or a refractive index control layer, on the thin film encapsulation layer TFE.

The base layer BS may include a synthetic resin layer. The synthetic resin layer may include a thermosetting resin. For example, the synthetic resin layer may be a polyimide-based resin layer, but the material of the base layer BS is not particularly limited thereto. The synthetic resin layer may include at least one of an acrylic resin, a methacrylic resin, a polyisoprene resin, a vinyl resin, an epoxy resin, a urethane-based resin, a celluosic resin, a siloxane-based resin, a polyamide resin, and a perylene-based resin. The base layer BS may include a glass substrate, a metal substrate, or an organic/inorganic composite substrate. The base layer BS may include a first polyimide layer, a second polyimide layer, and an inorganic layer disposed between the first polyimide layer and the second polyimide layer.

A buffer layer BFL including at least one inorganic layer may be disposed on the upper surface of the base layer BS. The buffer layer BFL may include at least one of aluminum oxide, titanium oxide, silicon oxide, silicon nitride, silicon oxy nitride, zirconium oxide, and hafnium oxide. The inorganic layer may be formed of multiple layers. The buffer layer BFL may prevent infiltration of foreign matter from the outside. The buffer layer BFL may improve the coupling force between the base layer BS and a semiconductor pattern and/or a conductive pattern disposed on the buffer layer BFL.

A silicon semiconductor layer may be disposed on the buffer layer BFL. The silicon semiconductor layer may include multiple semiconductor patterns. In an embodiment, a semiconductor pattern may be a silicon semiconductor pattern SP5. The silicon semiconductor pattern SP5 may be the semiconductor pattern of the fifth transistor T5.

The silicon semiconductor pattern SP5 may include a silicon semiconductor. For example, the silicon semiconductor may include amorphous silicon or polycrystalline silicon. For example, the silicon semiconductor pattern SP5 may include poly-silicon crystallized at a low temperature (hereinafter, referred to as the crystalline poly-silicon).

The silicon semiconductor pattern SP5 may have an electrical property depending on whether doping is performed or not. The fifth source S5, the fifth drain D5, and the channel area described with reference to FIG. 3A may be formed from the silicon semiconductor pattern SP5. The fifth source S5, the fifth drain D5, and the channel area may correspond to a fifth source area S5, a fifth drain area D5, and a fifth channel area A5 of FIG. 5. The fifth source area S5 and the fifth drain area D5 may extend from the fifth channel area A5 in opposite directions. Hereinafter, for convenience of description, the silicon semiconductor pattern SP5 may be defined as a third semiconductor pattern SP5. In an embodiment, the fifth source area S5 may be defined as a fifth input area, and the fifth drain area D5 may be defined as a fifth output area. Although the fifth transistor T5 of a P-type has been described as an embodiment, the fifth source area S5 and the fifth drain area D5 may be oppositely defined if the fifth transistor T5 is of an N-type.

Although not separately illustrated, the semiconductor pattern of the sixth transistor T6 described with reference to FIG. 4A and the third semiconductor pattern SP5 may be disposed on a same layer. The semiconductor pattern of the sixth transistor T6 and the third semiconductor pattern SP5 may be formed through a same process and may include a same semiconductor. The third semiconductor pattern SP5 and a first semiconductor pattern SP1 and a second semiconductor pattern SP2 described below may be disposed different insulating layers. In case that the third semiconductor pattern SP5 and the first and second semiconductor patterns SP1 and SP2 are disposed on different insulating layers, the third semiconductor pattern SP5 and the first and second semiconductor patterns SP1 and SP2 may contact upper surfaces of different insulating layers.

In FIGS. 3A and 4A, the fifth transistor T5 and the sixth transistor T6 may include a crystalline poly silicon semiconductor pattern, and thus the response speeds of the fifth transistor T5 and the sixth transistor T6 may be increased. This is because the crystalline poly silicon semiconductor pattern has faster mobility than other semiconductors.

The first insulating layer 10 may be disposed on the buffer layer BFL and cover the third semiconductor pattern SP5. In an embodiment, the first insulating layer 10 may be an inorganic layer and/or an organic layer and may have a single-layer structure or a multi-layer structure. In an embodiment, the first insulating layer 10 may include silicon oxide, silicon nitride, or silicon oxy nitride.

A conductive layer (hereinafter, referred to as the first conductive layer) may be disposed on the first insulating layer 10. The first conductive layer may include multiple conductive patterns (hereinafter, referred to as the first conductive patterns). Referring to FIG. 5, the first conductive patterns may include the fifth gate electrode G5 and the second voltage line VL2. The fifth gate electrode G5 may correspond to the fifth gate G5 of FIG. 3A, and the fifth gate electrode G5 and the fifth channel area A5 may have substantially a same area in a plan view.

In FIG. 5, the second voltage line VL2 divided in two is illustrated. However, the disclosure is not limited thereto. The second voltage line VL2 divided in two may have a one-body shape. It is sufficient that a conductive pattern receiving the second power supply voltage ELVDD is disposed on the first insulating layer 10, and the second voltage line VL2 does not necessarily have to be disposed on the first insulating layer 10.

The second insulating layer 20 may be disposed on the first insulating layer 10 and cover the first conductive layer. In an embodiment, the second insulating layer 20 may be an inorganic layer and/or an organic layer and may have a single-layer structure or a multi-layer structure. In an embodiment, the second insulating layer 20 may include silicon oxide, silicon nitride, or silicon oxy nitride.

A conductive layer (hereinafter, referred to as the second conductive layer) may be disposed on the second insulating layer 20. The second conductive layer may include multiple conductive patterns (hereinafter, referred to as the second conductive patterns). Referring to FIG. 5, the second conductive patterns may include a conductive pattern CP. The conductive pattern CP may correspond to the first lower gate G1-2 and the second electrode E2-2 of the second capacitor C2 in FIG. 3A. The conductive pattern CP may form the second capacitor C2 of FIG. 3A together with the second voltage line VL2 disposed under the conductive pattern CP.

The third insulating layer 30 may be disposed on the second insulating layer 20 and cover the second conductive layer. In an embodiment, the third insulating layer 30 may be an inorganic layer and/or an organic layer and may have a single-layer structure or a multi-layer structure. In an embodiment, the third insulating layer 30 may include silicon oxide, silicon nitride, or silicon oxy nitride.

A metal oxide semiconductor layer may be disposed on the third insulating layer 30. The metal oxide semiconductor layer may include multiple semiconductor patterns. In an embodiment, the first semiconductor pattern SP1 and the second semiconductor pattern SP2 may include different metal oxide semiconductors and disposed on the third insulating layer 30. The first semiconductor pattern SP1 may be the semiconductor pattern of the first transistor T1 of FIG. 3A, and the second semiconductor pattern SP2 may be the semiconductor pattern of the second transistor T2 of FIG. 3A. Although not separately illustrated, the semiconductor patterns of the third transistor T3 and the fourth transistor T4 described with reference to FIG. 3A and the second semiconductor pattern SP2 may be formed through a same process and may include a same semiconductor.

The first semiconductor pattern SP1 may include a crystalline oxide semiconductor, and the second semiconductor pattern SP2 may include an amorphous oxide semiconductor. The first semiconductor pattern SP1 may include a crystalline indium gallium oxide (IGO) semiconductor, and the second semiconductor pattern SP2 may include an amorphous indium tin gallium zinc oxide (ITGZO) semiconductor. Compared to a transistor including a silicon semiconductor, a transistor including an oxide semiconductor may have an advantage of low leakage current.

Each of the first semiconductor pattern SP1 and the second semiconductor pattern SP2 may include multiple areas distinguished from each other depending on whether metal oxide is reduced or not. The area where the metal oxide is reduced (hereinafter, referred to as the reduced area) may have a higher conductivity than the area where the metal oxide is not reduced (hereinafter, referred to as the non-reduced area). The reduced area may substantially serve as the source area, the drain area, or the signal transmission area of the transistor. The non-reduced area may substantially correspond to the channel area (or, the semiconductor area or the non-reduced area) of the transistor. In other words, a portion of the semiconductor pattern may be the channel area of the transistor, another portion may be the source area or the drain area of the transistor, and the other portion may be the signal transmission area.

The first source S1, the first drain D1, and the channel area described with reference to FIG. 3A may be formed from the first semiconductor pattern SP1. The first source S1, the first drain D1, and the channel area may correspond to a first source area S1, a first drain area D1, and a first channel area A1 of FIG. 5. The first source area S1 and the first drain area D1 may extend from the first channel area A1 in opposite directions. In an embodiment, the first drain area D1 may be defined as a first input area, and the first source area S1 may be defined as a first output area. Although the first transistor T1 of an N-type has been described as an embodiment, the first drain area D1 and the first source area S1 may be oppositely defined if the first transistor T1 is of a P-type.

The second source S2, the second drain D2, and the channel area described with reference to FIG. 3A may be formed from the second semiconductor pattern SP2. The second source S2, the second drain D2, and the channel area may correspond to a second source area S2, a second drain area D2, and a second channel area A2 of FIG. 5. The second source area S2 and the second drain area D2 may extend from the second channel area A2 in opposite directions. In an embodiment, the second drain area D2 may be defined as a second input area, and the second source area S2 may be defined as a second output area. Although the second transistor T2 of an N-type has been described as an embodiment, the second drain area D2 and the second source area S2 may be oppositely defined if the second transistor T2 is of a P-type.

The fourth insulating layer 40 may be disposed on the first semiconductor pattern SP1 and the second semiconductor pattern SP2. In an embodiment, the fourth insulating layer 40 may include silicon oxide, silicon nitride, or silicon oxy nitride.

In an embodiment, the fourth insulating layer 40 may not be entirely formed on the third insulating layer 30 and overlap only the channel areas of the transistors in a plan view. The fourth insulating layer 40 may include multiple insulating patterns. In FIG. 5, a first insulating pattern 40-1 and a second insulating pattern 40-2 are illustrated as an embodiment. In an embodiment of the disclosure, the fourth insulating layer 40 may entirely overlap the third insulating layer 30 in a plan view without being subjected to patterning.

A conductive layer (hereinafter, referred to as the third conductive layer) may be disposed on the fourth insulating layer 40. The first upper gate electrode G1-1 may be disposed on the first insulating pattern 40-1, and the second gate electrode G2 may be disposed on the second insulating pattern 40-2. The first upper gate electrode G1-1 and the second gate electrode G2 may correspond to the first upper gate G1-1 and the second gate G2 of FIG. 3A, respectively.

Since the insulating layer is etched using the first upper gate G1-1 and the second gate G2 as a mask after the first upper gate G1-1 and the second gate G2 are formed, the first insulating pattern 40-1 and the first upper gate G1-1 may have substantially a same shape in a plan view. For the same reason, the second insulating pattern 40-2 and the second gate electrode G2 may have substantially a same shape in a plan view. The edge of the gate electrode and the edge of the insulating pattern that overlap each other may be aligned with each other.

A fifth insulating layer 50 may be disposed on the third insulating layer 30. The fifth insulating layer 50 may cover the first upper gate electrode G1-1 and the second gate electrode G2. In an embodiment, the fifth insulating layer 50 may be an inorganic layer and/or an organic layer and may have a single-layer structure or a multi-layer structure. In an embodiment, the fifth insulating layer 50 may include silicon oxide, silicon nitride, or silicon oxy nitride.

A conductive layer (hereinafter, referred to as the fourth conductive layer) may be disposed on the fifth insulating layer 50. The fourth conductive layer may include multiple conductive patterns (hereinafter, referred to as the fourth conductive patterns). Referring to FIG. 5, the fourth conductive patterns may include three types of connecting electrodes CNE1, CNE2, and CNE3.

The first connecting electrode CNE1 connected to at least one of the first source area S1 and the first drain area D1 may be disposed on the fifth insulating layer 50. In FIG. 5, two first connecting electrodes CNE1 connected to the first source area S1 and the first drain area D1, respectively, are illustrated. Each of the first connecting electrodes CNE1 may be connected to a corresponding one of the first source area S1 and the first drain area D1 through a contact hole CH1 that penetrates the fifth insulating layer 50.

A first connecting electrode CNE1 may electrically connect the first source area S1 and the conductive pattern CP. The first connecting electrode CNE1 may be connected to the conductive pattern CP through a contact hole CH2 that penetrates the third insulating layer 30 and the fifth insulating layer 50.

The second connecting electrode CNE2 connected to at least one of the second source area S2 and the second drain area D2 may be disposed on the fifth insulating layer 50. In FIG. 5, two second connecting electrodes CNE2 connected to the second source area S2 and the second drain area D2, respectively, are illustrated as an embodiment. Each of the second connecting electrodes CNE2 may be connected to a corresponding one of the second source area S2 and the second drain area D2 through a contact hole CH1 that penetrates the fifth insulating layer 50.

The third connecting electrode CNE3 connected to at least one of the fifth source area S5 and the fifth drain area D5 may be disposed on the fifth insulating layer 50. In FIG. 5, two third connecting electrodes CNE3 connected to the fifth source area S5 and the fifth drain area D5, respectively, are illustrated as an embodiment. Each of the third connecting electrodes CNE3 may be connected to a corresponding one of the fifth source area S5 and the fifth drain area D5 through a contact hole CH3 that penetrates the first insulating layer 10, the second insulating layer 20, the third insulating layer 30, and the fifth insulating layer 50. Unlike in FIG. 5, one connecting electrode may connect the first drain area D1 and the fifth drain area D5.

A sixth insulating layer 60 may be disposed on the fifth insulating layer 50. The sixth insulating layer 60 may cover the connecting electrodes CNE1, CNE2, and CNE3. In an embodiment, the sixth insulating layer 60 may be an organic layer and may have a single-layer structure, but the disclosure is not particularly limited thereto.

A conductive layer (hereinafter, referred to as the fifth conductive layer) may be disposed on the sixth insulating layer 60. The fifth conductive layer may include multiple conductive patterns. The fifth conductive layer may include a fourth connecting electrode CNE4. The fourth connecting electrode CNE4 may be connected to the first connecting electrode CNE1 through a contact hole CH4 that penetrates the sixth insulating layer 60.

The fifth conductive layer may further include the data line DLj and the first voltage line VL1. The data line DLj may be connected to the second connecting electrode CNE2 through a contact hole CH4 that penetrates the sixth insulating layer 60. A portion of the first voltage line VL1 that overlaps the first electrode AE of the light emitting element OLED in a plan view described below may define the second electrode E3-2 of the third capacitor C3 illustrated in FIG. 3A. A portion of the first electrode AE of the light emitting element OLED may define the first electrode E3-1 of the third capacitor C3 illustrated in FIG. 3A.

A seventh insulating layer 70 may be disposed on the sixth insulating layer 60 and cover the fifth conductive layer. In an embodiment, the seventh insulating layer 70 may be an organic layer and may have a single-layer structure, but the disclosure is not particularly limited thereto.

The first electrode AE of the light emitting element OLED may be disposed on the seventh insulating layer 70. The first electrode AE may be an anode. The first electrode AE may be connected to the fourth connecting electrode CNE4 through a contact hole CH5 that penetrates the seventh insulating layer 70. A pixel defining layer PDL may be disposed on the seventh insulating layer 70.

An opening OP of the pixel defining layer PDL may expose at least a portion of the first electrodes AE. The opening OP of the pixel defining layer PDL may define an emissive area LA. For example, the pixels PX (refer to FIG. 2) may be arranged on the display panel 141 according to a certain rule. The area where the pixels PX are disposed may be defined as a display area, and the display area may include multiple emissive areas LA and a non-emissive area NLA adjacent to the emissive areas LA. The non-emissive area NLA may surround the emissive area LA.

A hole control layer HCL may be commonly disposed in the emissive area LA and the non-emissive area NLA. A common layer, such as the hole control layer HCL, may be commonly formed in the multiple pixels PX. The hole control layer HCL may include a hole transport layer and a hole injection layer.

The emissive layer EML may be disposed on the hole control layer HCL. The emissive layer EML may be disposed only in an area corresponding to the opening OP. The emissive layer EML may be separately formed in each of the pixels PX.

Although the patterned emissive layer EML is illustrated according to an embodiment, the disclosure is not limited thereto, and in another embodiment, the emissive layer EML may be commonly disposed in the pixels PX. The commonly disposed emissive layer EML may generate white light or blue light. The emissive layer EML may have a multi-layer structure.

An electron control layer ECL may be disposed on the emissive layer EML. The electron control layer ECL may include an electron transport layer and an electron injection layer. The second electrode CE may be disposed on the electron control layer ECL. The electron control layer ECL and the second electrode CE may be commonly disposed in the pixels PX.

The thin film encapsulation layer TFE may be disposed on the second electrode CE. The thin film encapsulation layer TFE may be commonly disposed in the pixels PX. In an embodiment, the thin film encapsulation layer TFE may cover (e.g., directly cover) the second electrode CE. In an embodiment of the disclosure, a capping layer that directly covers the second electrode CE may be additionally disposed. In another embodiment of the disclosure, the stack structure of the light emitting element OLED may have a structure turned upside down from the structure illustrated in FIG. 5.

The thin film encapsulation layer TFE may include at least an inorganic layer or an organic layer. In an embodiment of the disclosure, the thin film encapsulation layer TFE may include two inorganic layers and an organic layer disposed between two inorganic layers. In an embodiment of the disclosure, the thin film encapsulation layer TFE may include multiple inorganic layers and multiple organic layers that are alternately stacked one above another.

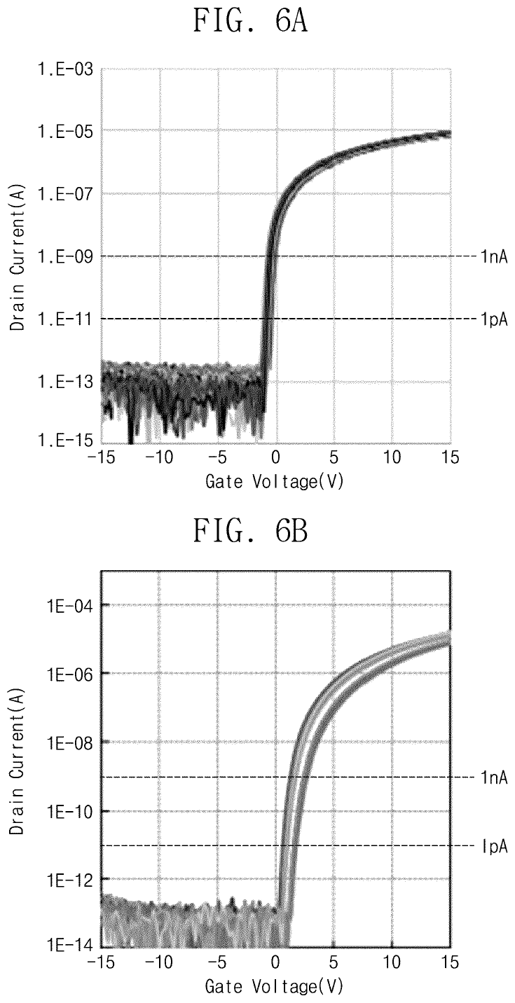

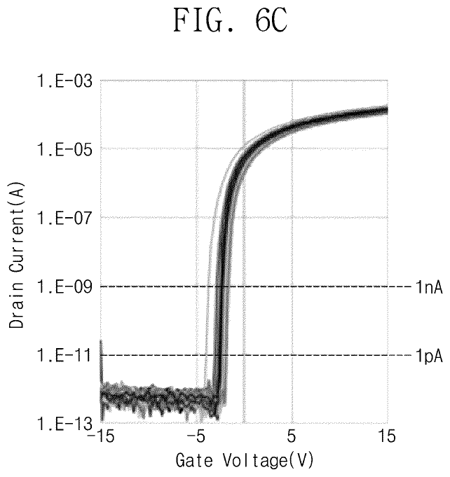

FIG. 6A is a graph depicting voltage-current characteristics of an oxide transistor according to a comparative example. FIG. 6B is a graph depicting voltage-current characteristics of an oxide transistor according to an embodiment of the disclosure. FIG. 6C is a graph depicting voltage-current characteristics of an oxide transistor according to an embodiment of the disclosure.

FIG. 6A shows voltage-current characteristics of a transistor including an amorphous indium gallium zinc oxide (IGZO) semiconductor. A low current-drive voltage range may be defined as a gate voltage range that determines a drain current in a range of 1 pA to InA. The low current-drive voltage range calculated from the graph of FIG. 6A is 0.49 V. A mobility of 28 cm²/Vs may be calculated from the graph of FIG. 6A.

FIG. 6B shows voltage-current characteristics of a transistor including a crystalline indium gallium oxide (IGO) semiconductor. The low current-drive voltage range calculated from the graph of FIG. 6B is 0.73 V. A mobility of 40 cm²/Vs may be calculated from the graph of FIG. 6B. Comparing FIG. 6A and FIG. 6B with each other, it can be seen that the mobility of the transistor including the crystalline indium gallium oxide (IGO) semiconductor is increased and the transistor has a wider low current-drive voltage range.

Since the first semiconductor pattern SP1 of the first transistor T1 includes a crystalline indium gallium oxide (IGO) semiconductor as described with reference to FIGS. 3A to 4B, the low-grayscale display quality of the display panel 141 may be improved. In case that a low current-drive voltage range is wide, a low current corresponding to a low grayscale may be controlled in steps. In case that a low current-drive voltage range is wide, current-voltage-luminance (IVL) characteristics may be improved.

FIG. 6C shows voltage-current characteristics of a transistor including an amorphous indium tin gallium zinc oxide (ITGZO) semiconductor. The low current-drive voltage range calculated from the graph of FIG. 6C is 0.35 V. A mobility of 64 cm²/Vs may be calculated from the graph of FIG. 6C. Comparing FIG. 6A and FIG. 6C with each other, it can be seen that a transistor including an amorphous indium tin gallium zinc oxide (ITGZO) semiconductor has a low current-drive voltage range similar to a transistor including an amorphous indium gallium zinc oxide (IGZO) semiconductor, but has a mobility two or more times greater than the transistor including an amorphous indium gallium zinc oxide (IGZO) semiconductor.

Since the second semiconductor pattern SP2 of the second transistor T2 includes an amorphous indium tin gallium zinc oxide (ITGZO) semiconductor as described with reference to FIGS. 3A to 4B, the response speed of the second transistor T2 may be increased. The area of the semiconductor pattern SP2 may be decreased. For example, the second semiconductor pattern SP2 may be designed as a short channel, and thus the area of the pixel circuit may be decreased.

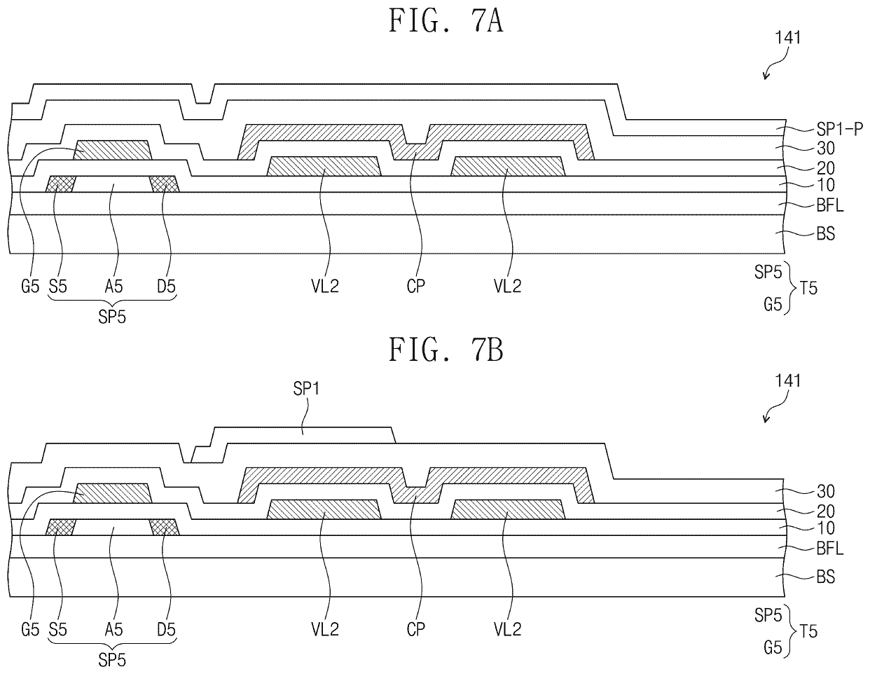

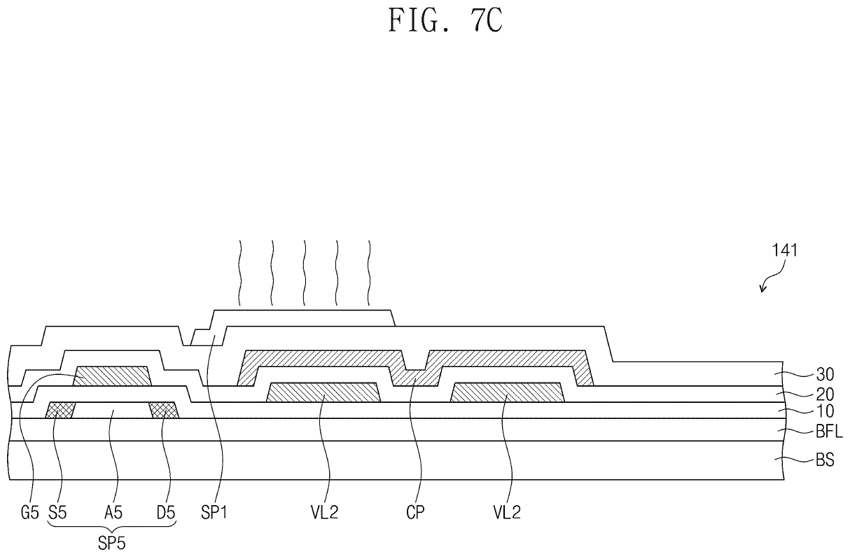

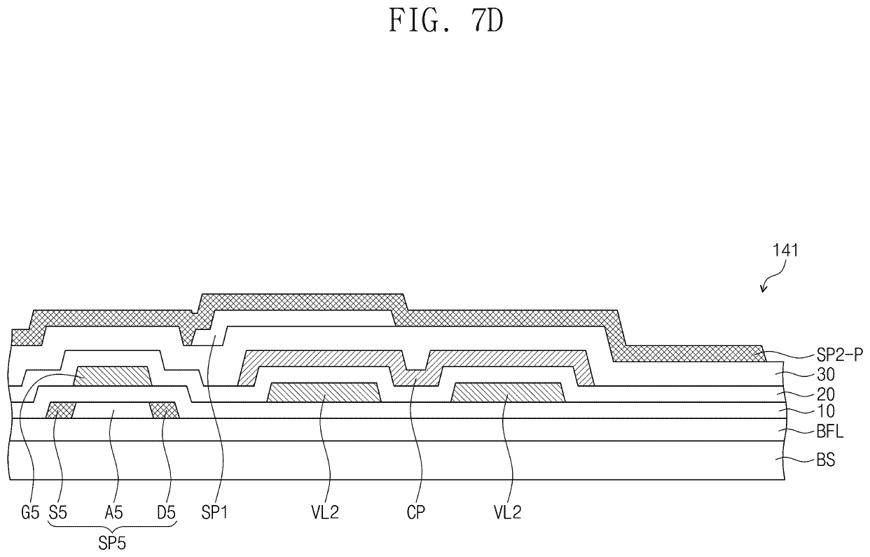

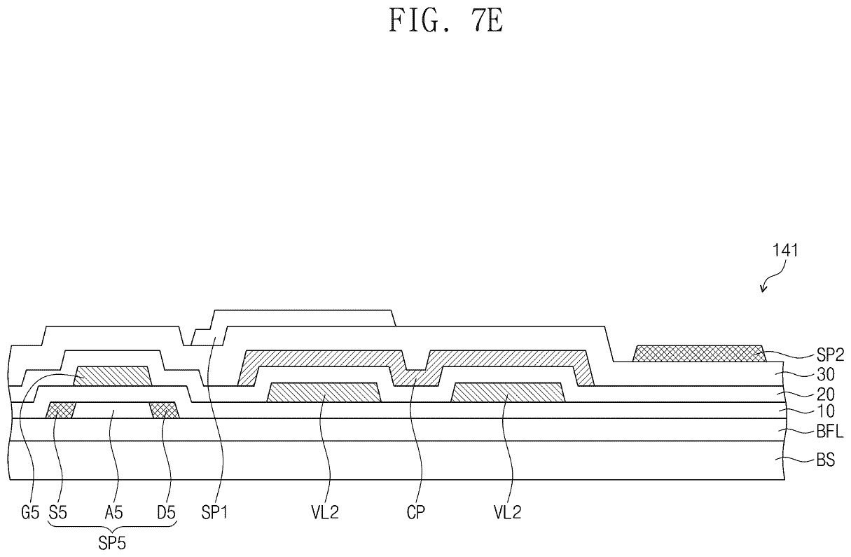

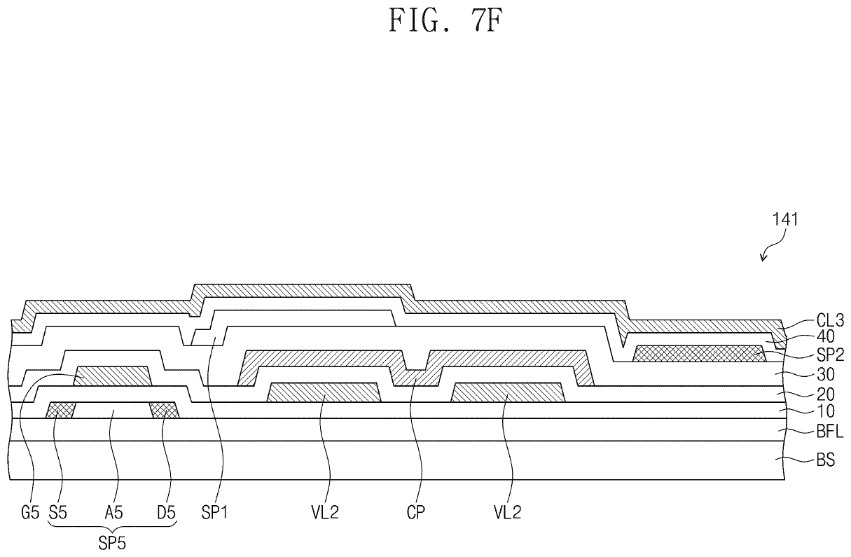

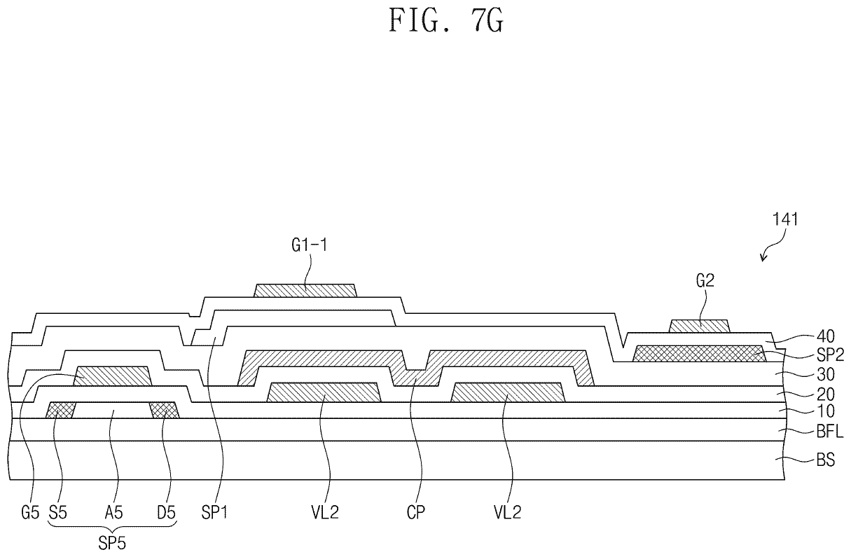

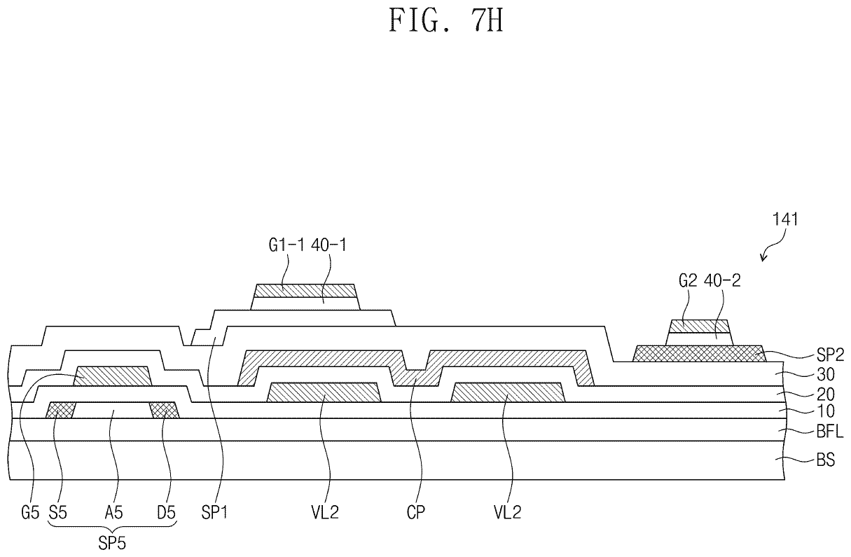

FIGS. 7A to 7H are schematic cross-sectional views illustrating a manufacturing process of the display panel 141 according to an embodiment of the disclosure. Hereinafter, detailed description of components identical to the components described with reference to FIG. 5 will be omitted.

As illustrated in FIG. 7A, the fifth transistor T5 may be formed on the base layer BS. As described with reference to FIG. 5, the fifth transistor T5 may include the silicon semiconductor pattern SP5 and the fifth gate G5.

First, the silicon semiconductor pattern SP5 and the first insulating layer 10 may be sequentially formed on the buffer layer BFL. A silicon semiconductor layer may be formed using a chemical vapor deposition (CVD) method. Thereafter, the silicon semiconductor pattern SP5 may be formed by patterning the silicon semiconductor layer through a photolithography process.

The first insulating layer 10 may be formed through a deposition process. For example, an inorganic material may be deposited using a plasma enhanced chemical vapor deposition (PECVD) method.

The first conductive layer including the first conductive patterns may be formed on the first insulating layer 10. The fifth gate electrode G5 and the second voltage line VL2 may be formed through a photolithography process. Thereafter, the second insulating layer 20 may be formed on the first insulating layer 10.

The second conductive layer including the second conductive patterns may be formed on the second insulating layer 20. The conductive pattern CP may be formed through a photolithography process. Thereafter, the third insulating layer 30 may be formed on the second insulating layer 20.

A first oxide semiconductor layer SP1-P may be formed on the third insulating layer 30. The first oxide semiconductor layer SP1-P may be formed using a sputtering method or a metal organic chemical vapor deposition (MOCVD) method. The first oxide semiconductor layer SP1-P may include indium gallium oxide (IGO).

As illustrated in FIG. 7B, the first semiconductor pattern SP1 may be formed from the first oxide semiconductor layer SP1-P. The first oxide semiconductor layer SP1-P may be patterned through a photolithography process.

As illustrated in FIG. 7C, the first semiconductor pattern SP1 may be crystallized. The amorphous indium gallium oxide (IGO) may be changed into crystalline indium gallium oxide (IGO) by providing heat to the first semiconductor pattern SP1.

As illustrated in FIG. 7D, a second oxide semiconductor layer SP2-P may be formed on the second insulating layer 20 to cover the first semiconductor pattern SP1. The second oxide semiconductor layer SP2-P may be formed using a sputtering method or a metal organic chemical vapor deposition (MOCVD) method. The second oxide semiconductor layer SP2-P may include indium tin gallium zinc oxide (ITGZO). The indium tin gallium zinc oxide (ITGZO) may be amorphous.

As illustrated in FIG. 7E, the second semiconductor pattern SP2 may be formed from the second oxide semiconductor layer SP2-P. The second semiconductor pattern SP2 may be spaced apart from the first semiconductor pattern SP1 in a cross-sectional view. The second oxide semiconductor layer SP2-P may be patterned through a photolithography process, and a wet etch process may be performed. The crystalline indium gallium oxide (IGO) may not be damaged by an etchant used in the wet etch process.

As illustrated in FIG. 7F, the fourth insulating layer 40 and the third conductive layer CL3 may be continuously formed on the third insulating layer 30. The fourth insulating layer 40 may be formed using a plasma enhanced chemical vapor deposition (PECVD) method. The third conductive layer CL3 may be formed through a sputtering method.

As illustrated in FIG. 7G, the third conductive layer CL3 may be patterned through a photolithography process. The first upper gate electrode G1-1 and the second gate electrode G2 may be formed from the third conductive layer CL3.

As illustrated in FIG. 7H, the fourth insulating layer 40 may be patterned using the first upper gate electrode G1-1 and the second gate electrode G2 as a mask. The first insulating pattern 40-1 and the second insulating pattern 40-2 may be formed from the fourth insulating layer 40. The first insulating pattern 40-1 may expose the first source area S1 and the first drain area D1, and the second insulating pattern 40-2 may expose the second source area S2 and the second drain area D2.

After that, the display panel 141 described with reference to FIG. 5 may be completed by additionally performing a subsequent process. For example, a process of forming an additional insulating layer and a process of forming a metal layer may be performed. For example, a process of forming the light emitting element OLED may be further performed. Thereafter, a process of forming the thin film encapsulation layer TFE may be additionally performed. These processes are not limited to special processes.

As described above, the low current drive voltage range of the first transistor may be widened, and thus the current-voltage-luminance characteristics may be improved, and the low-grayscale display quality may be improved.

The mobility of the second transistor may be increased so that a short-channel transistor may be implemented. The occupied area of the second transistor may be decreased so that the degree of freedom in design of the pixel circuit may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a plurality of insulating layers;
a light emitting element; and
a pixel circuit electrically connected to the light emitting element, wherein
the pixel circuit includes:
a first transistor that is configured to control a driving current of the light emitting element and includes a first semiconductor pattern including a crystalline indium gallium oxide semiconductor; and
a second transistor that is configured to output a data voltage and includes a second semiconductor pattern including an amorphous indium tin gallium zinc oxide semiconductor.

2. The display device of claim 1, wherein the first semiconductor pattern and the second semiconductor pattern are in contact with an upper surface of a same one among the plurality of insulating layers.

3. The display device of claim 1, wherein
the first transistor further includes a first gate electrode and a second gate electrode,
the first semiconductor pattern comprises a first channel area, a first input area, and a first output area,
the first gate electrode is located over the first channel area, and
the second gate electrode is located under the first channel area and electrically connected with the first output area.

4. The display device of claim 1, further comprising:
a third transistor including a third semiconductor pattern including a silicon semiconductor.

5. The display device of claim 4, wherein
the third semiconductor pattern is in contact with an upper surface of one of the plurality of insulating layers, and
the first semiconductor pattern and the second semiconductor pattern are in contact with an upper surface of another one of the plurality of insulating layers.

6. The display device of claim 4, further comprising:
a voltage line that is configured to receive a power supply voltage and is disposed under the first semiconductor pattern, wherein
the third transistor further includes a gate electrode located over the third semiconductor pattern, and
the gate electrode of the third transistor and the voltage line are spaced apart from each other in a plan view and are in contact with an upper surface of a same one among the plurality of insulating layers.

7. The display device of claim 6, further comprising:
a conductive pattern located between the first semiconductor pattern and the voltage line, wherein
the conductive pattern overlaps the first semiconductor pattern and the voltage line in a plan view, and
an output area of the first semiconductor pattern and the conductive pattern are electrically connected with each other.

8. The display device of claim 1, further comprising:
a third transistor connected between a voltage line that is configured to receive a first voltage and a gate electrode of the first transistor;
a fourth transistor connected between a voltage line that is configured to receive a second voltage and a first electrode of the light emitting element; and
a fifth transistor connected between a voltage line that is configured to receive a first power supply voltage and the first transistor,
wherein a second electrode of the light emitting element is configured to receive a second power supply voltage different from the first power supply voltage.

9. The display device of claim 8, further comprising:
a sixth transistor connected between the first transistor and the first electrode of the light emitting element.

10. The display device of claim 8, wherein a semiconductor pattern of each of the third transistor and the fourth transistor and the second semiconductor pattern include a same semiconductor.

11. The display device of claim 10, wherein the semiconductor pattern of each of the third transistor and the fourth transistor and the second semiconductor pattern are in contact with an upper surface of a same one among the plurality of insulating layers.

12. The display device of claim 8, wherein the fifth transistor includes a third semiconductor pattern including a silicon semiconductor.

13. An electronic device comprising:
a display device; and
an input device that is configured to receive a command, an input, or a data from outside, wherein
the display device includes:
a plurality of insulating layers;
a light emitting element; and
a pixel circuit electrically connected to the light emitting element, and
the pixel circuit includes:
a first transistor that is configured to control a driving current of the light emitting element and includes a first semiconductor pattern including a crystalline indium gallium oxide semiconductor; and
a second transistor that is configured to output a data voltage and includes a second semiconductor pattern including an amorphous indium tin gallium zinc oxide semiconductor.

14. The electronic device of claim 13, wherein the input device is an input sensor, a keyboard, or a mouse.

15. The electronic device of claim 13, wherein the first semiconductor pattern and the second semiconductor pattern are in contact with an upper surface of a same one among the plurality of insulating layers.

16. The electronic device of claim 13, wherein
the first transistor further includes a first gate electrode and a second gate electrode,
the first semiconductor pattern comprises a first channel area, a first input area, and a first output area,
the first gate electrode is located over the first channel area, and
the second gate electrode is located under the first channel area and electrically connected with the first output area.

17. The electronic device of claim 13, further comprising:
a third transistor including a third semiconductor pattern including a silicon semiconductor, wherein
the third semiconductor pattern is in contact with an upper surface of one of the plurality of insulating layers, and
the first semiconductor pattern and the second semiconductor pattern are in contact with an upper surface of another one of the plurality of insulating layers.

18. A method for manufacturing a display device, the method comprising:
forming a first semiconductor pattern on an insulating layer;
crystallizing the first semiconductor pattern;
forming, on the insulating layer, a second semiconductor layer that covers the first semiconductor pattern; and
forming a second semiconductor pattern to be spaced apart from the first semiconductor pattern in a plan view by patterning the second semiconductor layer, wherein
the first semiconductor pattern includes an indium gallium oxide semiconductor, and
the second semiconductor pattern includes an indium tin gallium zinc oxide semiconductor.

19. The method of claim 18, further comprising:
forming a first gate electrode over the first semiconductor pattern; and
forming a second gate electrode over the second semiconductor pattern.

20. The method of claim 19, further comprising:
forming, between the first semiconductor pattern and the first gate electrode, an insulating pattern that exposes portions of the first semiconductor pattern.
